(19) United States
(12) Patent Application Publication
(10) Pub. No.: US 2016/0260848 A1
(43) Pub. Date: Sep. 8, 2016

(54) Method for Laser Curing of Anti-Reflective Coatings

(71) Applicant: First Solar, Inc., Perrysburg, OH (US)

(72) Inventor: Nathan Martin Schuh, Perrysburg, OH (US)

(73) Assignee: First Solar, Inc., Perrysburg, OH (US)

(21) Appl. No.: 15/057,715

(22) Filed: Mar. 1, 2016

Related U.S. Application Data
(60) Provisional application No. 62/127,411, filed on Mar. 3, 2015.

(51) Int. Cl. H01L 31/0216; H01L 31/0224; H01L 31/18; H01L 31/073; H01L 31/068; C23C 16/02; H01L 31/042

(52) U.S. Cl. CPC H01L 31/02168; C23C 16/0263; H01L 31/022466; H01L 31/042; H01L 31/073; H01L 31/068; H01L 31/186

(57) ABSTRACT

A method of curing anti-reflective coatings, and photovoltaic modules produced using the method, are described.

### RELATED APPLICATIONS

This application claims the benefit of U.S. Provisional Application No. 62/127,411, filed under 35 U.S.C. §111(b) on Mar. 3, 2015, the entire disclosure of which is hereby incorporated by reference for all purposes.

### BACKGROUND OF THE INVENTION

An anti-reflective coating (“ARC”) is a type of low reflectivity coating applied to the surface of a transparent article to reduce reflectance of visible light from the article and enhance the transmission of such light into or through the article. ARCs are useful in photovoltaic modules for such purposes. ARCs can include inorganic coatings made of titanium, titanium dioxide, titanium nitride, chromium oxide, carbon, or α-silicon, as well as organic coatings made of a light-absorbing substance and a polymer. ARCs can be deposited on the surface glass substrates by numerous methods, such as, but not limited to, the sol-gel method and vacuum deposition methods (known as conventional deposition, “CD”) in which the materials to be deposited are heated to a molten state, chemical vapor deposition (“CVD”), ion-assisted deposition (“IAD”) in which the film being deposited is bombarded with energetic ions of an inert gas during the deposition, and ion beam sputtering (“IBS”) in which an energetic beam is directed to a target material. Of these methods, the sol-gel method involves a low cost of materials and utilizes ambient pressures and temperatures. However, the sol-gel method generally involves curing in order to evaporate residual organics and other liquid components from the adhered layer, as well as to complete the matrix bonding and densify the coating structure and make the coating robust against chemical attack and abrasion from hard particles. Under-cured films are subject to chemical decomposition. It would be advantageous to develop improved methods of curing antireflective films under low temperature conditions.

### BRIEF DESCRIPTION OF THE DRAWING

The patent or application file contains one or more drawings executed in color and/or one or more photographs. Copies of this patent or patent application publication with color drawing(s) and/or photograph(s) will be provided by the U.S. Patent and Trademark Office upon request and payment of the necessary fees.

FIG. 1: Diagram of a non-limiting example of an antireflective coating in a photovoltaic module.

FIG. 2: Graph showing solar spectral transmittance of five window glasses commonly used in photovoltaic modules.

FIG. 3: Graph showing the results of a laser curing simulation. The variables assumed for the simulation are defined in the legend.

FIG. 4: Photograph of a sample following laser curing and abrasion, looking at the reflection of a ceiling light on the abraded area of a 30×30 cm coupon. The writing is on the antireflective (“AR”) side of the glass.

FIGS. 5A-5C: Photographs of a sample showing progressive damage to the coating with an increasing number of abrasion cycles. The encircled numbers indicate the number of abrasion cycles.

FIG. 6: Graph showing specular reflection as a bivariate fit of average R360-740 nm by cycle number. The film visibly appears to be gone at 25 cycles.

FIG. 7: Graph showing diffuse reflection as a bivariate fit of average R360-740 nm by cycle number.

FIG. 8A: Graph of reflection versus abrasion test (denoted CS10F) cycles for various glass samples with an antireflective coating cured by a CO₂ laser using different power and scan speed settings.

FIG. 8B: Graph showing a bivariate fit of the data shown in FIG. 8A.

FIG. 9A: Photograph of a sample with a normal AR coating near the center of the coupon.

FIG. 9B: Photograph under 20× magnification of a heated spot, heated by a conventional oven curing process, of the sample depicted in FIG. 9A.

FIG. 9C: Photograph under 20× magnification of the unheated spot of the sample depicted in FIG. 9A.

### DETAILED DESCRIPTION OF THE INVENTION

Throughout this disclosure, various publications, patents, and published patent specifications are referenced by an identifying citation. The disclosures of these publications, patents, and published patent specifications are hereby incorporated by reference into the present disclosure in their entirety to more fully describe the state of the art to which this invention pertains.

All ranges disclosed herein are to be understood to encompass the beginning and ending range values and any and all subranges subsumed therein. For example, a stated range of “1 to 10” should be considered to include any and all subranges between (and inclusive of) the minimum value of 1 and the maximum value of 10; that is, a state range of “1 to 10” should be considered to include any and all subranges beginning with a minimum value of 1 or more and ending with a maximum value of 10 or less, such as 1 to 3.3, 4.7 to 7.4, 5.5 to 10, and the like.

In the present disclosure, when a layer is described as being disposed or positioned “on” another layer or substrate, it is to be understood that the layers can either be directly contacting each other or have one (or more) layer or feature between the layers. Further, the term “on” describes the relative position of the layers to each other and does not necessarily mean “on top of” since the relative position above or below depends upon the orientation of the device to the viewer. Moreover, the use of “top,” “bottom,” “above,” “below,” and variations of these terms is made for convenience, and does not require any particular orientation of the components unless otherwise stated. Likewise, a layer that is “disposed on” a different layer does not necessarily imply that the two layers are in direct contact with one another and may allow for the presence of intervening layers. In contrast, the term “adjacent” is used to imply that two layers are in direct physical contact. Furthermore, the terms “on top of,” “formed over,” “deposited over,” and “provided over” mean formed, deposited, provided, or located on a surface but not necessarily in direct contact with the surface. For example, a coating layer “formed over” a substrate does not preclude the presence of one or more other coating layers or films of the same or different composition located between the formed coating layer and the substrate. The term “transparent” as used herein refers to material that allows an average transmission of at least 70% of incident electromagnetic radiation having a wavelength in a range of from about 300 nm to about 850 nm.

The sol-gel method is a versatile low-temperature solution process for making inorganic ceramic and glass materials. In general, the sol-gel method involves the transition of a system from a liquid “sol” (mostly colloidal) into a solid “gel” phase. The starting materials used in the preparation of the “sol” are usually alkoxides. In a typical sol-gel method, the precursor is subjected to a series of hydrolysis and condensation polymerization reactions to form a colloidal suspension, or a “sol.” Hydrolysis of an alkoxide liberates alcohol and results in polymerized chains of metal hydroxide. For example, silica gels can be formed by hydrolysis of tetraethoxysilicate, Si(OC₂H₅)₄, based on the formation of silicon oxide, SiO₂, and ethyl alcohol, C₂H₅OH. The gel coating is then cured to remove the liquid phase and leave a strongly crosslinked solid material (when properly cured), which may be porous. This sol-gel method is valuable for the development of coatings because it is easy to implement and provides films of generally uniform composition and thickness.

Most sol-gel antireflective coatings are cured by exposure to high temperature in an infrared or convection oven, and are often applied to raw glass at the beginning of the PV module manufacturing process. The cure process takes several minutes and works best at around 600° C. Upon curing, the coatings become much harder, but are still prone to scratching and other damage in transport through manufacturing processes. It would therefore be ideal to apply an antireflective coating at the end of the module manufacturing process. However, the interlayer of a module conducts a significant amount of heat to the back glass, and as a result, the high temperatures involved with conventional curing techniques, such as the high temperatures attained in an oven, would destroy a finished module. Some coatings can be cured at a temperature below 200° C. for about 1 hour, and are thus feasibly compatible with application to finished modules. However, the long process time for these curing processes requires a large complex oven. Also, coatings cured at low temperature are not quite as strong as their high-temperature-cured counterparts. Therefore, it has been thought that applying an antireflective coating to a finished photovoltaic module would require a lower temperature cure process.

Provided herein is a method of curing an ARC that limits the duration of high glass surface temperature, thereby minimizing the risk to the module packaging and internal components. Further provided are the resulting photovoltaic modules produed using this method. The method involves the use of a gas laser, such as a carbon dioxide (CO₂) laser, to cure the coating. Those skilled in the art will understand that a gas laser is one in which an electric current is discharged through a gas in order to produce coherent light. In the case of a carbon dioxide laser, the gas includes carbon dioxide and other gases such as helium, xenon, hydrogen, and nitrogen. The method can be utilized to manufacture a photovoltaic module from any type of suitable solar cell semiconductor. These include, but are not limited to, CdTe-based semiconductors (for instance, those having a rectifying junction between p-type or high resistivity CdTe and doped or undoped n-type CdS); and silicon-based semiconductors.

By very briefly heating the coating with a laser, the coating's temperature (as well as the outer glass surface of the solar module) can reach any desired temperature, even beyond the melting point of glass. After the laser heat source is removed, the thin hot region at the glass surface, from about 10 μm to about 100 μm deep, quickly dissipates its heat into the underlying glass (thousands of micrometers), ultimately raising the substrate temperature by only a few degrees, thereby preventing damage to the module's internal structures. The laser does not heat the glass significantly enough to cause damage to underlying PV devices. In a typical laser-curing process, the temperature of the glass may increase by about 2° C., whereas glass subjected to other curing processes may be as much as 30° C. or more hotter afterward.

A carbon dioxide laser produces 10.6 μm light, which is absorbed very strongly in the glass, having an absorption depth of about 10 μm. Large industrial CO₂ lasers are currently used for applications such as cutting metal, and are well-suited, with the attachment of appropriate guiding optics, to perform an ARC-curing process. In accordance with this disclosure, an ARC cured with a high peak energy for a short time can become several times stronger than an ARC cured through other methods. By way of non-limiting examples, the cured coating may have twice or three-times the hardness as the uncured coating. Furthermore, the faster the surface is heated, the less heat soaks into the glass, and the greater the efficiency of the cure. A laser is therefore ideal for this purpose, as the use of a laser to cure an ARC also reduces the amount of time the coating surface is exposed to high energy. Conventional methods may require exposure to heat for a second or more, whereas curing with a laser can effectively cure the film upon exposure for a duration of 10 s or 100 s of milliseconds. In some embodiments, the use of a laser can cure a coating with microsecond-long exposures to temperatures near or above the melting point of glass.

Due to the very high power density of a laser, it is possible to produce extreme temperatures at the surface of irradiated objects, while leaving the temperature only hundreds of micrometers below the surface quite low. The high-intensity energy rapidly heats the surface such that heat will not sink into the glass. Thus, CO₂ laser curing of ARCs on glass permits high-temperature curing of the ARCs and other thin films while leaving most of the underlying substrate at a lower temperature and delivering little thermal exposure to the semiconductor and interlayer. This allows for coatings composed of, for example, nanoporous silicon dioxide, to be sintered together or otherwise cured, resulting in greater strength and ease of integration into thermally sensitive PV manufacturing processes.

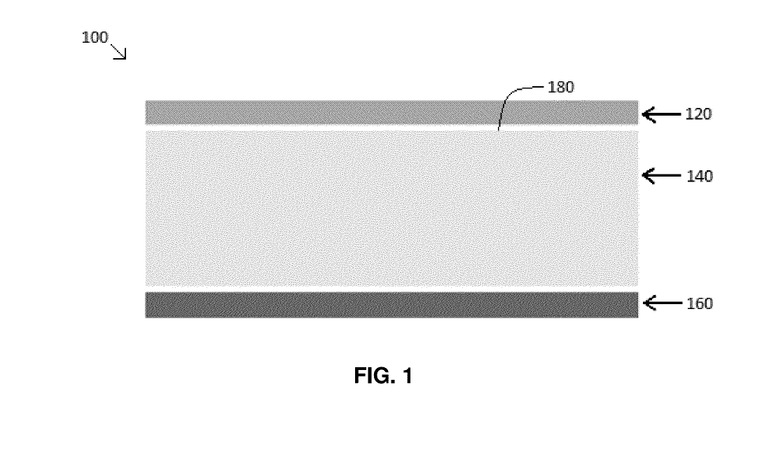

Also provided are the photovoltaic modules produced by the laser curing method described. Referring now to FIG. 1, a typical ARC in a photovoltaic module 100 provides a porous silica coating layer 120 on top of a glass substrate 140, the glass substrate 140 being on top of a solar cell semiconductor 160. The glass substrate 140 may be soda-lime glass, low-iron glass, borosilicate glass, flexible glass, or other type of glasses or transparent substrates such as crystalline oxides and optical plastics. One non-limiting example of such an ARC is a colloidal suspension of silica particles in a solvent, such as water, an alcohol, or mixtures thereof. The suspension can include organic compounds in various forms and for various purposes, such as compounds designed to prevent the particles in suspension from clinging together. Generally, the ARC is applied while wet to the surface 180 of glass through any suitable method such as, but not limited to, roll-coating, dip-coating, spin coating, spray coating, wire rod coating, doctor blade coating, meniscus coating, slot die coating, capillary coating, curtain coating, or extrusion. After the coating process, a substantial amount of the solvent rapidly evaporates, usually within a few seconds (for example, up to about 5 seconds), leaving a substantially dry coating 120 on the surface 180 of the glass. This glass surface 180 is nonetheless hydrated, as the dry coating 120 is weakly bound to the surface 180 of the glass through SiOH bonds. A curing process is then conducted on the dry coating. In the case of a Si-based sol-gel coating, the exposure to heat or other energy during the curing process condenses the SiOH to yield water and SiO₂, leaving the film well adhered to the glass surface. Also during this process, any remaining solvent and residual organic compounds are driven off or evaporated. The result is a much stronger coating of SiO₂ on the glass surface 180. Such a SiO₂ coating 120 can be of many different thicknesses. In one non-limiting example, the SiO₂ coating 120 is about 100 nm thick.

In the exemplary embodiment depicted in FIG. 1, the incoming or incident light from the sun or the like is first incident on the ARC 120, passing through the ARC 120 and then through the glass substrate 140 before reaching the solar cell semiconductor 160. The photovoltaic module 100 may further include, but does not require, additional layers such as, but not limited to, a reflection enhancement oxide, a transparent conductive oxide, and a back metallic or otherwise conductive contact and/or reflector. The ARC may reduce reflections of the incident light and permit more light to reach the solar cell semiconductor 160, thereby permitting the photovoltaic module 100 to act more efficiently.

The cure process is dependent upon the power density (W/cm²), duration, and uniformity of the beam, as well as the spectrum of the light. Uniformity across the area of exposure is also important. For this reason, a flat, tophat profile beam is preferable. A CO₂ laser is particularly useful for curing an anti-reflective coating because the spectrum of light emitted by CO₂, having a wavelength of about 10 μm, is strongly absorbed by glass. Most of the laser energy passes through the coating and is absorbed in the underlying glass substrate. Since the coating is so thin compared to the heated glass below (in certain non-limiting examples, about 0.1 μm versus about 10 μm), this heat can quickly diffuse into the overlying coating before it soaks in to the cool glass below. The coating is generally much thinner than the heated substrate, and the heated substrate is generally much thinner than the un-heated substrate.

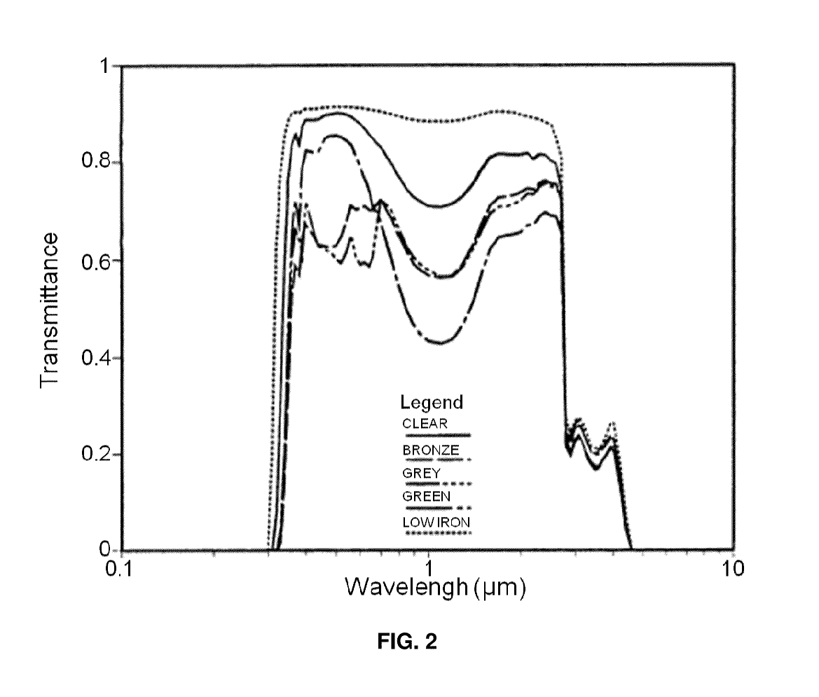

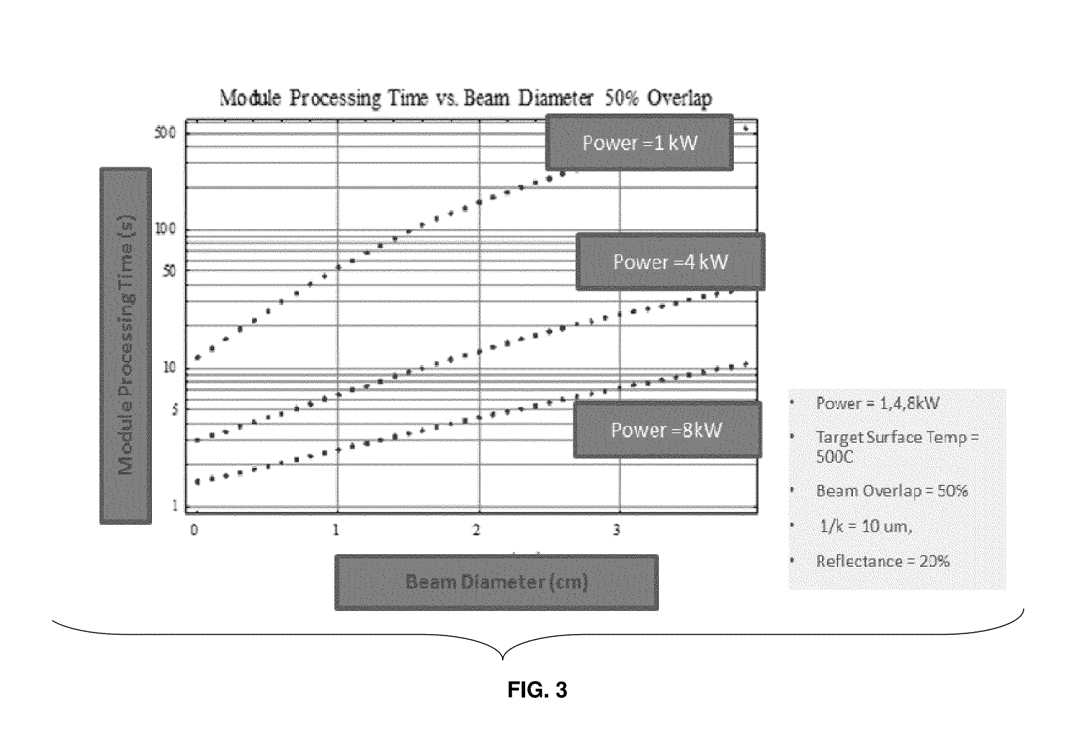

A CO₂ laser is absorbed in glass with an absorption depth of about 10 μm. FIG. 2 shows the solar spectral transmittance of five common window glasses in solar modules. As seen from this figure, glass is quite transparent to shorter wavelengths of 0.3-5 μm. FIG. 3 shows the results of a laser curing simulation using the variables shown. This simulation used an analytical solution to the heat transfer equation for an exponentially attenuated heat load to determine time required to process a module. From this simulation, it is clear that the requisite module processing time is reduced by increasing the power density of the laser.

Many industrial lasers used in applications such as welding, cutting, and surface hardening operate in the range of 2-10 kW, and would be suitable to cure an antireflective coating on a glass substrate in a photovoltaic module. Though CO₂ lasers are described for illustrative purposes as being especially suitable for curing an antireflective coating, other types of lasers can also be employed. Suitable other lasers include, but are not limited to, carbon monoxide IR lasers and excimer UV lasers. It is to be understood that either continuous wave or pulsed lasers can be used to cure an ARC. A continuous wave laser is one which has an output power that remains constant over time, and a pulsed laser is a laser which is not a continuous wave laser. Pulsed lasers have been used for thermal annealing of encapsulation layers (that is, metal layers, metal sulfide layers, dielectric layers, or semiconductor layers) in photovoltaic modules, as described in WO 2013189939 A1. When the laser is a pulsed laser, a duration in the range of 10 ns to 10 ms can be used. In particular non-limiting examples, the duration is in the range of between about 100 ns and 300 ns, or between about 100 ns and 200 ns.

There are many advantages to the use of a CO₂ laser to cure an ARC. CO₂ lasers ranging in power from 1 kW to 20 kW are readily available and allow for fast processing. The process is scalable and efficient. Using a large CO₂ laser (4-8 kW), it is possible to cure entire modules at a rate greater than 4 modules per minute. CO₂ lasers are also more efficient in terms of power consumption than air convection systems. By way of a non-limiting example, a 4 kW laser consumes about 20-40 kW of electrical power, which can result in significant energy savings. The use of a laser to cure an ARC also has the distinct advantage of affording a wide process space and being a clean process. Furthermore, a laser cure process is considerably tunable. Both peak temperature and dwell time at the peak temperature can be set to cover nearly the full range obtainable by other methods such as convection oven curing.

A CO₂ laser process is sufficiently flexible to obtain a high enough temperature to cure the coating while still low enough not to decompose certain organic functional groups in the coating. This flexibility permits the use of these functional groups to tune properties like surface energy, hydrophobicity, and hydrophilicity. Thus, in certain embodiments, laser curing permits very high temperatures which cure films but do not degrade the hydrophobicity of the films. In other embodiments, the laser curing can exceed the melting temperature of applied coatings or glass substrate, which enables the use of binder-less or reactive antireflective coatings as well as textured glass surfaces. These applications can significantly enhance the light capturing properties of photovoltaic modules.

Those skilled in the art will recognize that there is an intensity threshold beyond which point the laser will damage the glass substrate. Because damage to the glass substrate is undesired, the intensity of the laser beam should remain below this intensity threshold for optimal effect. Using an absorption coefficient α=0.1 μm⁻¹, the surface temperature of the glass substrate can reach 400° C. with a 100 μs exposure of power 12.7 kW/cm² (10 kW over 1 cm diameter circle) without damaging the glass. As an approximate calculation for the rastering velocity necessary, a non-limiting example of a module has an area of about 7200 cm². At a rastering velocity of 100 μs/cm², processing of a full plate would require 0.72 seconds for a 12 kW laser. In this example, the raster velocity would need to be 100 meters per second at the module surface. As used herein, the term “rastering” refers to the process of sweeping a laser beam across a moving sample. Very small beam diameters necessitate very fast rastering. Elongating the beam proportionally slows the raster rate and decreases the required overlap.

Though Si-based sol-gels are described for illustrative purposes, other sol-gel ARCs can be used in a laser-curing process as described herein. The ARCs can be provided in the form of sol-gel precursor solutions that are applied to the glass substrate and then cured. Sol-gel precursors include, but are not limited to, metal and metalloid compounds having a hydrolysable ligand that can undergo a sol-gel reaction to form a sol-gel. Suitable hydrolysable ligands include, but are not limited to, hydroxyl, alkoxy, halo, amino, or acylamino groups. Silica is the most common metal oxide participating in the sol-gel reaction, though other metals and metalloids can also be used, such as, but not limited to, zirconia, vanadia, titania, niobium oxide, tantalum oxide, tungsten oxide, tin oxide, hafnium oxide, alumina, or mixtures or composites thereof having metal oxides, halides, or amines capable of reacting to form a sol-gel. Additional metal atoms that can be incorporated into the sol-gel precursors include magnesium, molybdenum, cobalt, nickel, gallium, beryllium, yttrium, lanthanum, tin, lead, and boron. In certain non-limiting examples, the precursors are silicon alkoxides, such as tetramethylorthosilane (TMOS), tetraethylorthosilane (TEOS), fluoroalkoxysilane, or chloroalkoxysilane; germanium alkoxides, such as tetraethylorthogermanium (TEOG); vanadium alkoxides; aluminum alkoxides; zirconium alkoxides; and titanium alkoxides. In some embodiments, the precursor is an alkoxide of silicon, germanium, aluminum, titanium, zirconium, vanadium, or hafnium, or mixtures thereof. Examples of such metal alkoxides include, but are not limited to, tetraethoxysilane, tetraethyl orthotitanate, and tetra-n-propyl zirconate. The sol-gel precursor can be in a solution that includes one or more acid or base catalysts for controlling the rates of hydrolysis and condensation. Non-limiting examples of suitable catalysts include hydrochloric acid, nitric acid, sulfuric acid, acetic acid, ammonium hydroxide, and tetramethylammonium hydroxide.

In a non-limiting example of the method described herein, an ARC precursor solution is laid down wet, with about 10% solids and 90% solvent, on a glass substrate on top of a solar cell semiconductor. In other embodiments, the ARC precursor solution has a solids content as low as about 1%, with up to about 99% solvent. A substantial amount of the solvent is allowed to evaporate over a short period of time, up to about five seconds, thereby leaving a substantially dry coating on the surface of the glass substrate. The substantially dry coating is then subjected to curing with the CO₂ laser, by exposing the coating to electromagnetic radiation from the CO₂ laser. The exposure removes most if not all solvent remaining in the pores of the coating, removes organic compounds in the pores of the coating, and causes chemical reactions between adjacent particles in the coating, causing the adjacent particles to chemically bond together and to the glass surface.

Additionally, non-sol-gel ARCs are also encompassed within this disclosure. Suitable non-sol-gel ARCs include, but are not limited to, acrylates, methacrylates, epoxides, hybrid silicone-organic polymers, urethanes, fluoropolymers, silicones, and polysilazanes. Certain polymers can be used “as is” to form an ARC; that is, an organic polymer can be dissolved in a solvent to form a polymer solution that is applied to the glass substrate and then cured with a laser. Laser curing can result in cross-linking and polymerization between organic monomers to form organic polymers such as acrylic polymers.

Any ARC may also include an additive such as a porogen, which assists or enhances pore formation so as to ensure the cured coating is porous or enhance the porosity of the cured coating. Suitable porogens include, but are not limited to, polymers, surfactants, or water-immiscible solvents. The porogen can be removed during drying or pyrolized during the curing process. In certain embodiments, the ARC includes a porogen selected from the group consisting of: polyethers, polyacrylates, aliphatic polycarbonates, polyesters, polysulfones, polystyrene, star polymers, cross-linked polymeric nanospheres, block copolymers, hyperbranched polymers, polycaprolactone; polyethylene terephthalate; poly(oxyadipoyloxy-1,4-phenylene); poly(oxyterephthaloyloxy-1,4-phenylene); poly(oxyadipoyloxy-1,6-hexamethylene); polyglycolide, polylactide (polylactic acid), polylactide-glycolide, polypyruvic acid, polycarbonate such as poly(hexamethylene carbonate) diol having a molecular weight from about 500 to about 2500, polyether such as poly(bisphenol A-co-epichlorohydrin) having a molecular weight from about 300 to about 6500, poly(methylmetacrylate), poly-gylcolids, polylactic acid, poly(styrene-co-α-methylstyrene, poly(styrene-ethyleneoxide), poly(etherlactones), poly(estercarbonates), poly(lactonelactide), hyperbranched polyester, polyethylene oxide, polypropylene oxide, ethylene glycol-poly(caprolactone), polyvinylpyridines, hydrogenated polyvinyl aromatics, polyacrylonitriles, polysiloxanes, polycaprolactams, polyurethanes, polydienes, hydrogenated polyvinyl aromatics, polyacrylonitriles, polysiloxanes, polycaprolactams, polyurethanes, polydienes, polyvinyl chlorides, polyacetals, amine-capped alkylene oxides, polyisoprenes, polytetrahydrofurans, polyethyloxazolines, polyalkylene oxide, a monoether of a polyalkylene oxide, a diether of a polyalkylene oxide, bisether of a polyalkylene oxide, an aliphatic polyester, an acrylic polymer, an acetal polymer, a poly(caprolactone), a poly(valeractone), a poly(methlylmethoacrylate), a poly(vinylbutyral), unfunctionalized polyacenaphthylene homopolymer, functionalized polyacenaphthylene homopolymer, polynorbornene, and combinations thereof

### EXAMPLES

Four 30×30 cm samples of hard Si-based antireflective coating, four 30×30 cm samples of normal Si-based AR coating, and two 30×30 cm samples of glass with no coating, were cured with a continuous wave 15 W CO₂ laser in a tabletop system. All pieces of glass had a tin oxide (SnO₂) TCO on the side opposite the AR coating. The tests generated a 2× increase in hardness relative to uncured coatings, which is very close to the increase produced from oven-cured coatings. Tests were conducted to determine if the damage threshold is different for the glass alone than for glass with an AR coating.

An abrasion test was conducted to demonstrate curing. A Taber Industries abrasion tester was set up to apply a constant 24 N normal force to the abrasion disk during testing. The hard AR coating required 2 to 3 times more abrasion cycles to remove than the normal AR coating. The hard AR coating also became harder at a slightly lower temperature. Similar results could be obtained by pressing firmly by hand and rubbing the disk back and forth until the coating was removed. The cured film remained following this process.

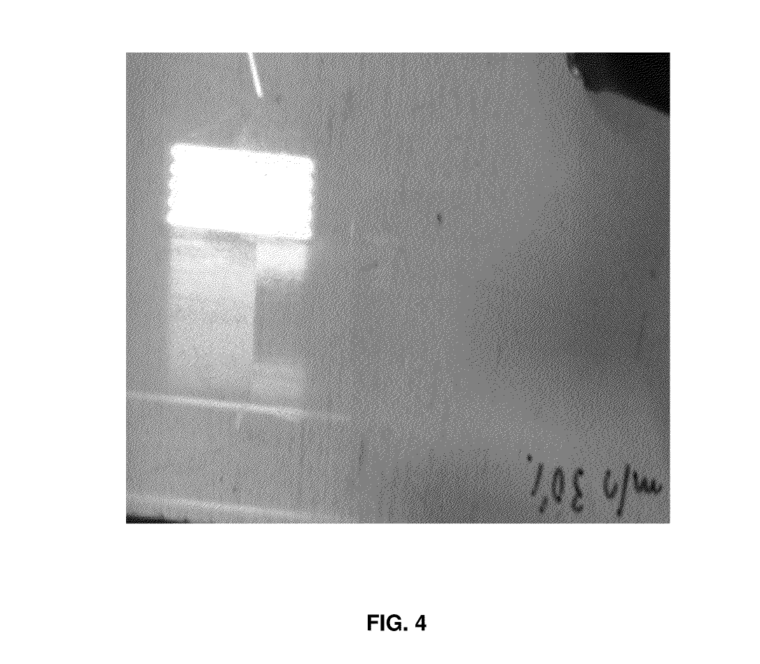

The laser was able to cure an 8×8 cm region of a 60×120 cm module in a time which, when scaled up, could process the full module in less than 15 seconds to a 4× increase in abrasion resistance. The power of the laser was increased until damage to the glass was observed, then the power was backed off and the abrasion test was conducted by hand to demonstrate the improvement in hardness. FIG. 4 shows a photograph of a sample following the laser curing and abrasion, looking at the reflection of a ceiling light on the abraded area of a 30×30 cm coupon. (The writing is on the AR coating side of the glass.) The photograph shows an unexposed abraded patch on the right of the sample, where the ARC is gone so the glass with no scratches is visible, and a laser-exposed region on the left of the sample, where scratches are visible because the ARC remained on the glass. Mild abrasion resulted in the removal of the uncured antireflective coating, while the cured coating remained on the glass.

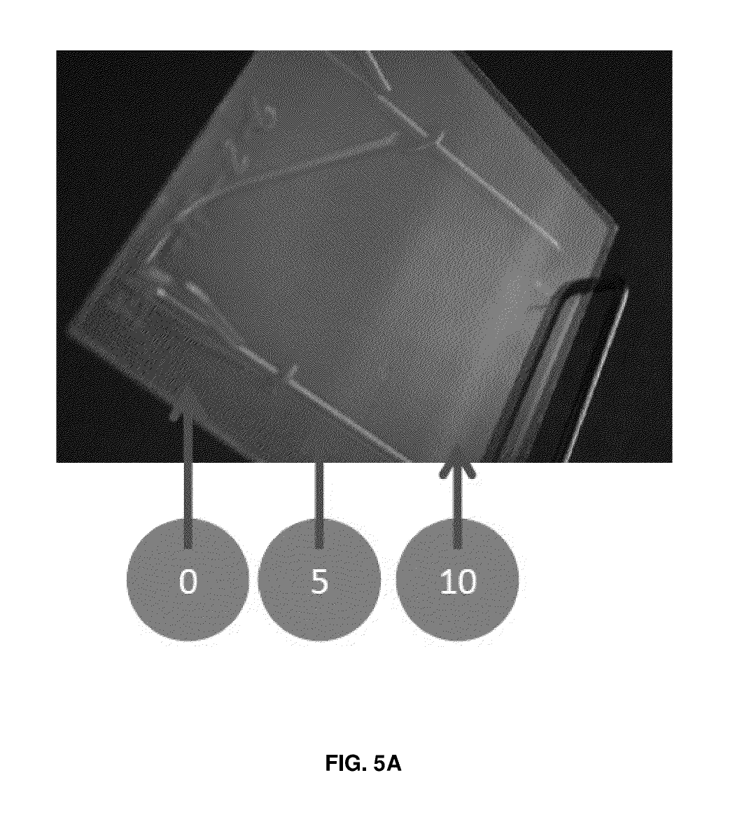

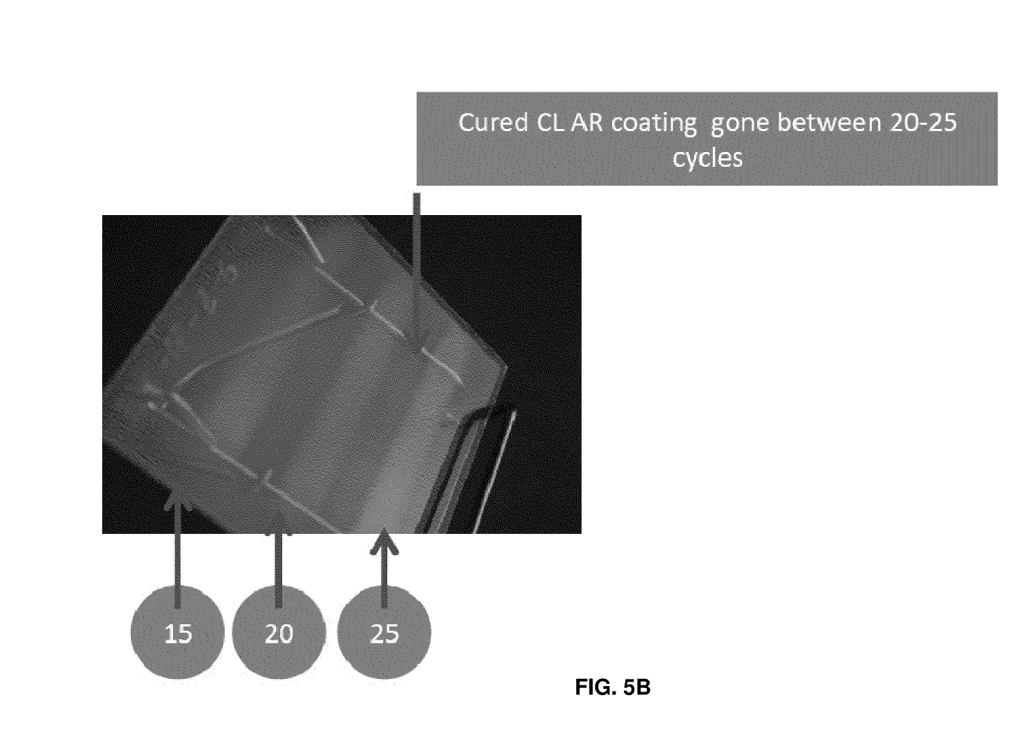

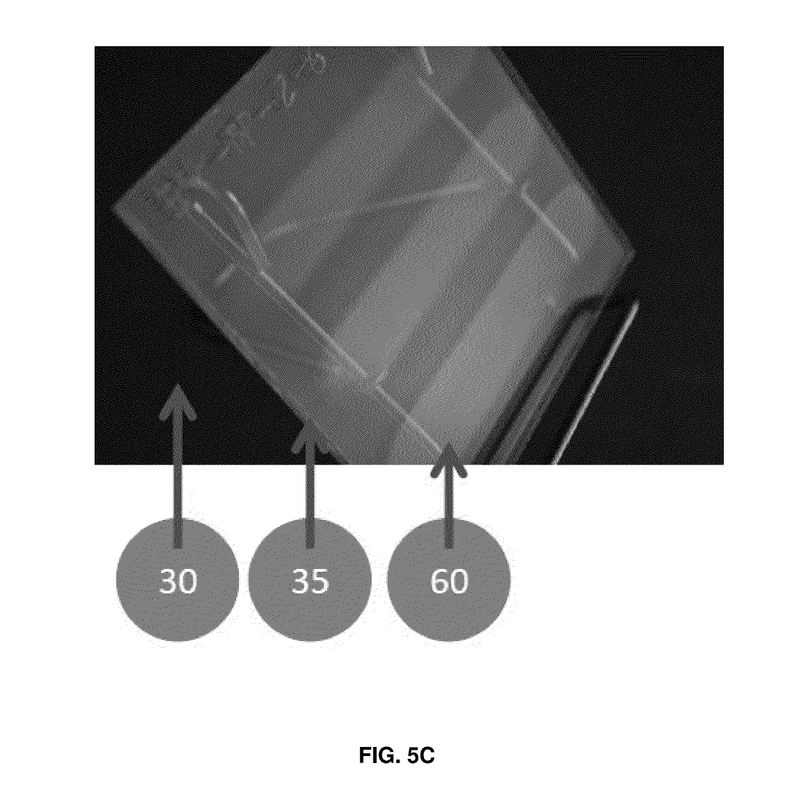

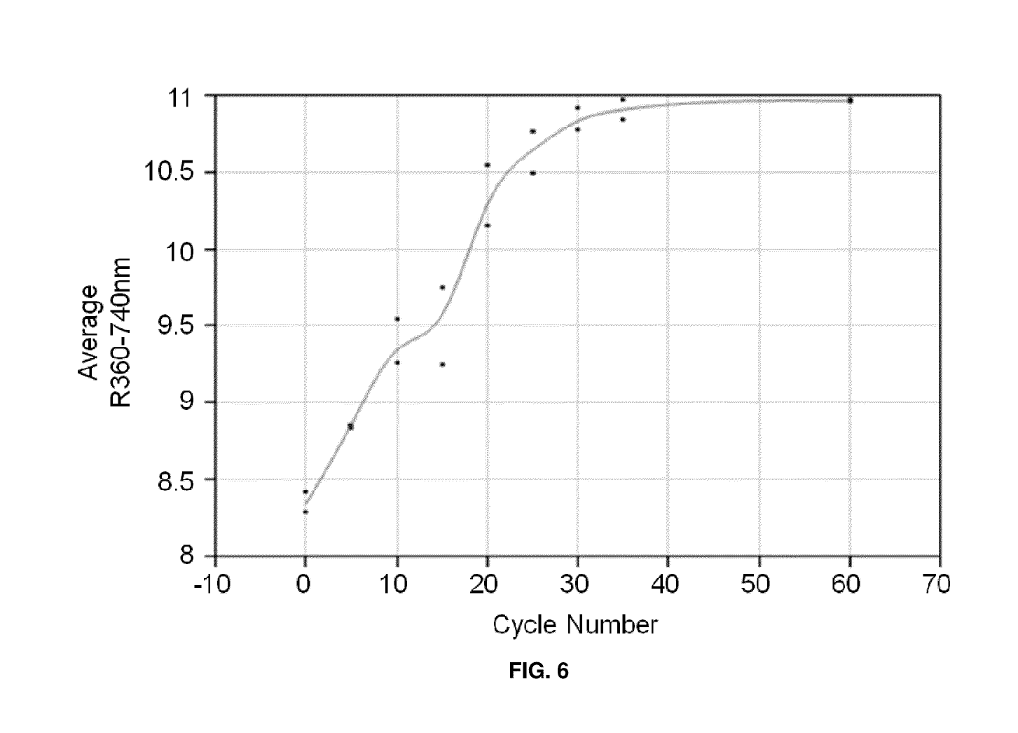

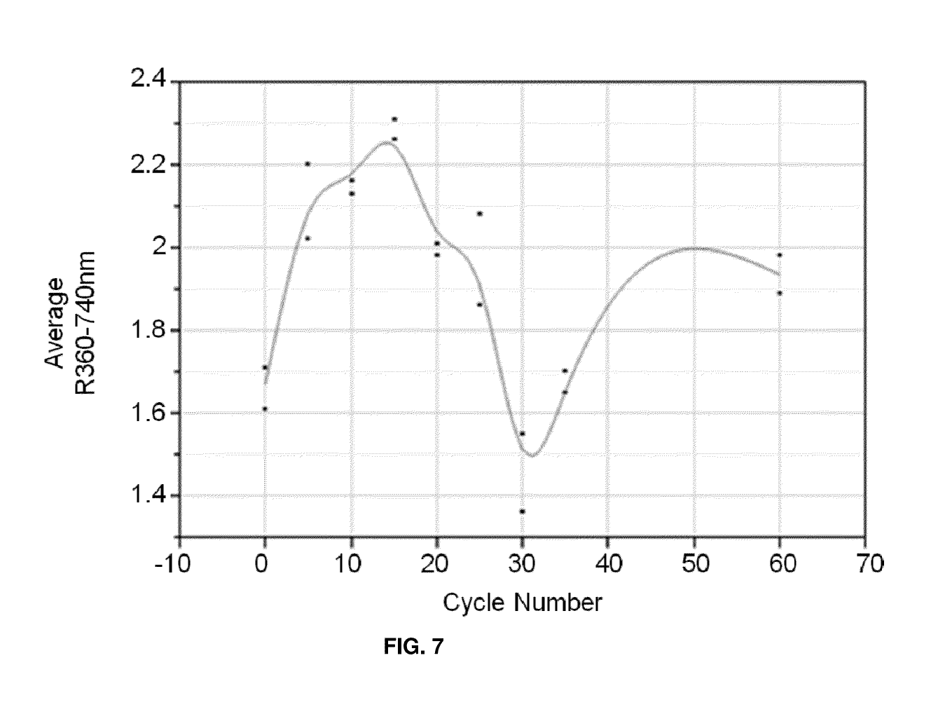

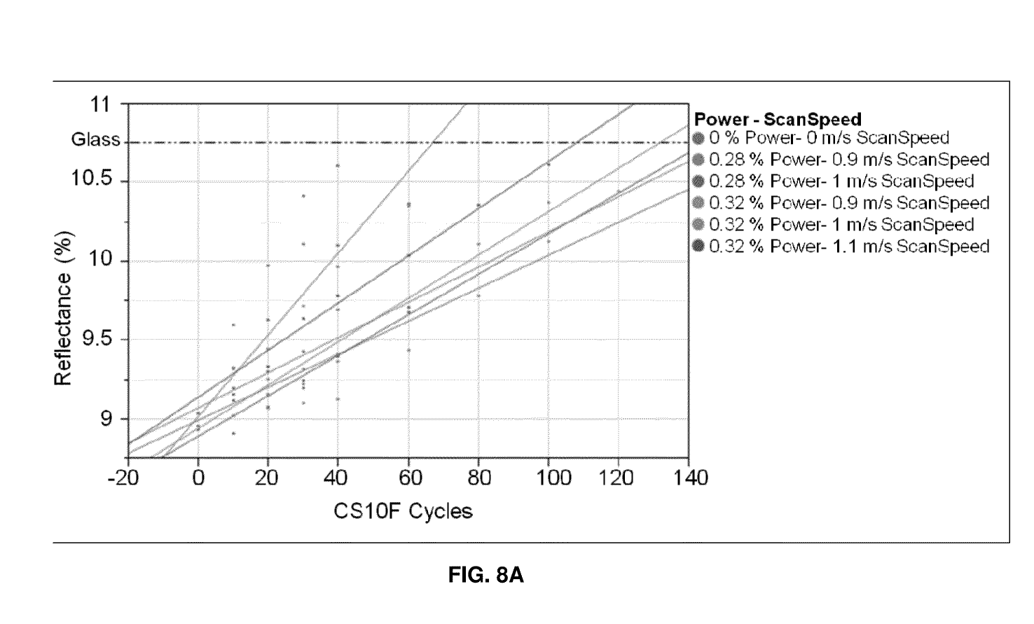

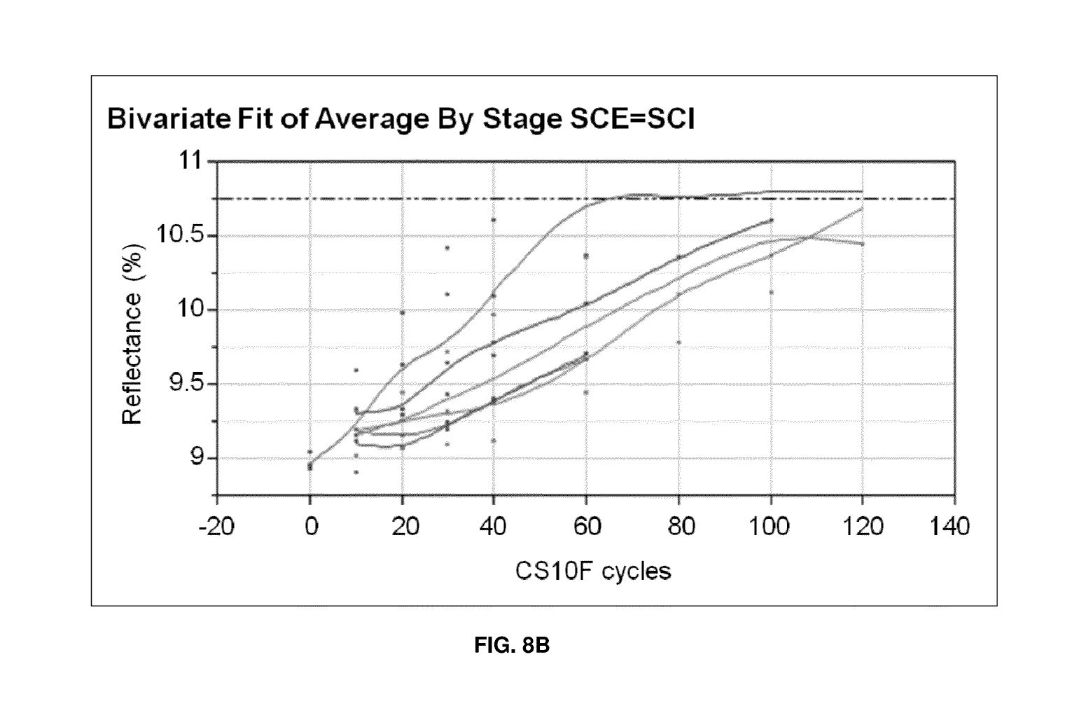

FIGS. 5A-5C show photographs of a particular sample with progressive damage to the coating with increasing numbers of abrasion cycles. Each abrasion cycle consisted 24 Newtons of downward force applied to the abrasion disk. Using this procedure, a fully cured coating endured more than 12 cycles, and was completely removed in 25 cycles. The total reflection data matches nicely with the visible observation, seen in FIGS. 5A-5C, that the film appears to be gone at 20-25 cycles. The reflection data, shown in the graphs in FIGS. 6-7, indicates that there are remnants near the edge of the track that remain until 30 cycles. There was no change in specular reflection from 30 to 60 cycles, but the diffuse reflection picked up the small glass scratches that appear. FIG. 8A shows a graph of reflection versus abrasion test (denoted CS10F) cycles for the samples cured using different power and scan speed settings. FIG. 8B shows a bivariate fit of this data. These results show that abrasion resistance had increased 2× over the unexposed regions.

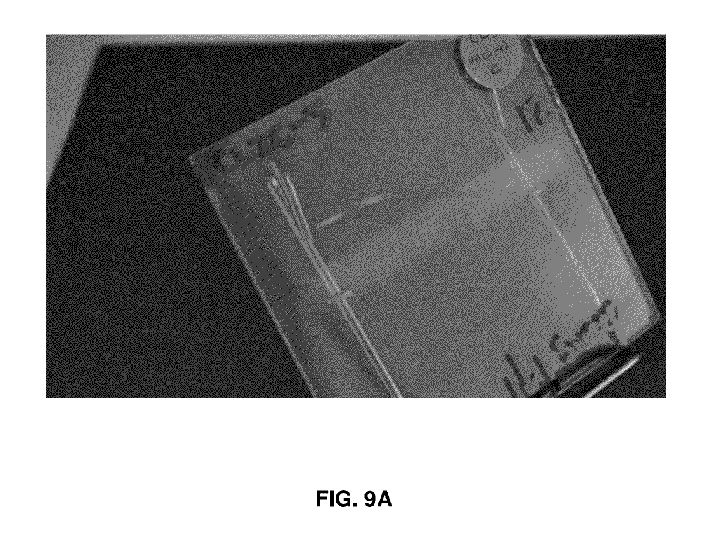

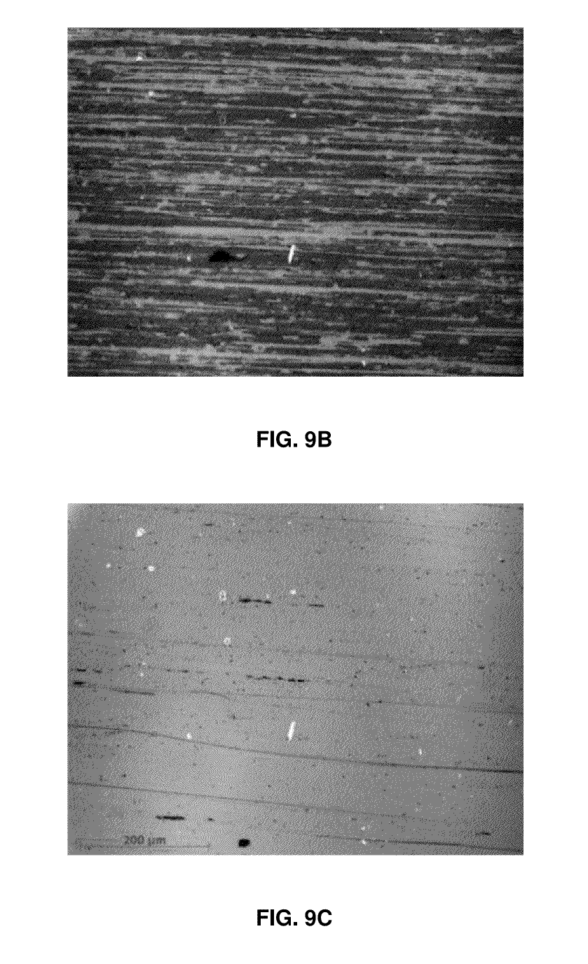

Samples that were conventionally cured were obtained for comparison purposes. FIG. 9A shows a spot cure of a normal AR coating near the center of the coupon. FIG. 9B shows a 20× microscope image of the heated spot (on the right side of the sample seen in FIG. 9A), which became tough and remained after 12 cycles of abrasion. FIG. 9C shows a 20× microscope image of the unheated spot (on the left side the sample seen in FIG. 9A). As seen in these images, the AR coating remained near the center of the abrasion track. After curing, the normal AR coating endured 12 cycles of abrasion, while the uncured AR coating was removed in about 6 cycles.

The laser-cured samples showed spots of weakness due to the non-uniform small beam used. A large beam reshaped to an elongated rectangle would show minimal effect from the non-uniformities.

Certain embodiments of the methods and photovoltaic modules disclosed herein are defined in the above examples. It should be understood that these examples, while indicating particular embodiments of the invention, are given by way of illustration only. From the above discussion and these examples, one skilled in the art can ascertain the essential characteristics of this disclosure, and without departing from the spirit and scope thereof, can make various changes and modifications to adapt the compositions and methods described herein to various usages and conditions. Various changes may be made and equivalents may be substituted for elements thereof without departing from the essential scope of the disclosure. In addition, many modifications may be made to adapt a particular situation or material to the teachings of the disclosure without departing from the essential scope thereof.

What is claimed is:

1. A method of curing an anti-reflective coating on glass, the method comprising exposing an uncured anti-reflective coating on glass to electromagnetic radiation from a laser to cure the anti-reflective coating on the glass.

2. The method of claim 1, the laser being a gas laser.

3. The method of claim 2, the gas laser being a CO₂ laser.

4. The method of claim 1, the glass being a glass substrate in a photovoltaic module.

5. The method of claim 1, the uncured anti-reflective coating comprising a suspension of silica particles in a solvent.

6. The method of claim 1, the glass coated with an anti-reflective coating being exposed to the electromagnetic radiation from the laser for a period of less than one second.

7. The method of claim 1, the laser being a continuous wave laser.

8. The method of claim 1, the laser having a power ranging from about 1 kW to about 20 kW.

9. The method of claim 1, the laser having a power ranging from about 4 kW to about 8 kW.

10. The method of claim 1, the laser having a power of about 15 kW.

11. The method of claim 1, the cured anti-reflective coating having at least twice the hardness as the uncured anti-reflective coating.

12. A product of the method of claim 1.

13. A method of assembling a photovoltaic module, the method comprising:
providing a glass substrate over a solar cell semiconductor;
coating the glass substrate with a wet anti-reflective coating to produce a coated glass surface, the anti-reflective coating comprising a suspension of particles in a solvent;
allowing a substantial amount of the solvent to evaporate, thereby forming a substantially dry anti-reflective coating on the glass surface; and
exposing the substantially dry anti-reflective coating to electromagnetic radiation from a CO₂ laser at a sufficient intensity and for a sufficient amount of time to cure the anti-reflective coating on the glass substrate and produce a photovoltaic module.

14. The method of claim 13, the substantial amount of the solvent evaporating within a time period of up to about 5 seconds.

15. The method of claim 13, the wet anti-reflective coating comprising about 1% solids and about 99% solvent.

16. A photovoltaic module comprising:
a glass substrate on top of a semiconductor layer; and
an antireflective coating cured on the glass substrate;
wherein the antireflective coating is cured by exposure to a laser.

17. The photovoltaic module of claim 16, the semiconductor layer comprising p-type CdTe and n-type CdS.

18. The photovoltaic module of claim 16, the semiconductor layer comprising a silicon-based semiconductor.

19. The photovoltaic module of claim 16, the antireflective coating comprising SiO₂ bonded to the glass substrate.

20. The photovoltaic module of claim 16, further comprising a transparent conductive oxide layer of SnO₂.
